(19) United States
(12) Patent Application Publication
(10) Pub. No.: US 2008/0280388 A1
(43) Pub. Date: Nov. 13, 2008

(54) CCD type solid-state imaging device and method for manufacturing the same

(76) Inventors: Kenji Ishida, Kurokawa-gun (JP); Masanori Nagase, Kurokawa-gun (JP)

Correspondence Address: BIRCH STEWART KOLASCH & BIRCH, PO BOX 747, FALLS CHURCH, VA, 22040-0747, US

(21) Appl. No.: 12/078,254

(22) Filed: Mar. 28, 2008

Related U.S. Application Data
(62) Division of application No. 11/790,026, filed on Apr. 23, 2007.

(30) Foreign Application Priority Data
Apr. 28, 2006 (JP) P2006-125054

(51) Int. Cl. H01L 31/18

(52) U.S. Cl. 438/60; 257/E31.084

(57) ABSTRACT

A CCD type solid-state imaging device is provided and includes: photodiodes (PD) in a light receiving area of a semiconductor substrate; vertical charge transfer paths; a horizontal charge transfer path; channel stops including linear high density impurity regions for separating mutually adjoining sets from each other, each set including a PD array and a vertical charge transfer path; a first light-shielding film which is stacked on the light receiving area and has openings in the respective PDs, and also to which a control pulse voltage is applied; a second light-shielding film spaced from the first light-shielding film for covering a connecting portion between the horizontal charge transfer path and light receiving area; and a contact portion of a high density impurity region for connecting the channel stops to the second light-shielding film and also for applying a reference potential to the channel stops.

This application is a Divisional of co-pending application Ser. No. 11/790,026, filed on Apr. 20, 2007, and for which priority is claimed under 35 U.S.C. § 120. This application claims priority of Application No. 2006-125054 filed in Japan on Apr. 28, 2006, respectively, under 35 U.S.C. § 119; the entire contents of all are hereby incorporated by reference.

### BACKGROUND OF THE INVENTION

1. Field of the Invention

The present invention relates to a CCD (Charged Coupled Devices) type solid-state imaging device and a method for manufacturing the same and, specifically, the invention relates to a CCD type solid-state imaging device which not only can improve the ground potential thereof but also is suitable to lower a read-out voltage and reduce smear, and a method for manufacturing such CCD type solid-state imaging device.

2. Description of Related Art

In a CCD type solid-state imaging device, in a p well layer of the surface portion of an n-type semiconductor substrate thereof, there are provided a large number of photodiodes (n regions) in an array manner and, beside each of the photodiode arrays, there is provided a vertical charge transfer path (VCCD). Also, in order to separate a set of a photodiode array and a vertical charge transfer path from its adjoining set of a photodiode array and a vertical charge transfer path, on the surface portion of the semiconductor substrate, there are provided a large number of channel stops which extend in the vertical direction in parallel to each other.

In the CCD type solid-state imaging device, these channel stops are used, while the end portions of the channel stops are respectively connected a ground potential (a reference potential: this is hereinafter referred to as a GND potential). However, since the channel stop includes a high density impurity region (p+ region) and thus has resistance, when a high read-out voltage (for example, +15V) is applied to the transfer electrode of the vertical charge transfer path that also functions as a read-out electrode, at the central position of a light receiving area distant from the ground connecting end of the channel stop, the GND potential varies locally to cause the incomplete reading of a signal charge, which leads to the unfinished reading of the signal charge.

To solve the above issue, in a technology disclosed in JP-A-11-177078, the channel stop is connected to a light-shielding film at a position near to the light receiving area, that is, at a position where the vertical charge transfer path is connected to a horizontal charge transfer path, and the light-shielding film is connected to the GND potential, thereby restricting the variation of the GND potential in the light receiving area.

To realize this connection, in JP-A-11-177078, the respective whole areas of photodiode forming areas at a portion near to the horizontal charge transfer path (a portion where the horizontal charge transfer path is covered with the light-shielding film) are filled up with the p+ region, and such p+ region is connected to the light-shielding film. In other words, the two sides of the vertical charge transfer path existing in the portion near to the horizontal charge transfer path are respectively held by and between the wide p+ regions.

The signal charge of the photodiode detected in the light receiving area is read out to the vertical charge transfer path, is transferred on the vertical charge transfer path and arrives at the horizontal charge transfer path. In the early stage of this transfer, the signal charge is transferred on the vertical charge transfer path held by and between the photodiodes (which include an n region provided within a p well layer); and, in the late stage of the transfer (just before it is transferred to the horizontal charge transfer path), the signal charge is transferred on the vertical charge transfer path held by and between the wide p+ regions. That is, the transfer early and late stages differ from each other in the physical condition of the periphery of the vertical charge transfer path.

Recently, in the CCD type solid-state imaging device, as the number of pixels employed therein has increased, it has been popular that several millions of pixels are incorporated in the CCD type solid-state imaging device; and thus, the width of the vertical charge transfer path has been narrowed greatly. Owing to this, when the physical conditions of the vertical charge transfer path vary between the early and late transfer stages, there is a fear that an inconvenience can occur in the transfer of the signal transfer.

Also, in the CCD type solid-state imaging device, when the light-shielding film is uniformly connected to the GND potential, there is raised the following issue. For example, in a solid-state imaging device disclosed in JP-A-7-153932, a high density impurity surface layer of a reverse conduction type (p type) is formed on the surface of an n-type semiconductor layer constituting a photoconductor, and a contact hole is opened up in an insulating layer to be stacked on the surface of a semiconductor substrate; and, the light-shielding film is electrically connected to the high density impurity surface layer through the contact hole.

And, by applying a given potential to the light-shielding film, the potential of the photodiode surface is set at a level lower than the pseudo-Fermi level of the high density impurity surface layer, or, by applying a potential lower than the surface potential of the photodiode to the light-shielding film, a small number of carriers (holes) generated due to photoelectric conversion are allowed to escape to the light-shielding film, thereby reducing the recombination of the signal charge (electron) and the small number of carriers.

In this manner, in the conventional CCD type solid-state imaging devices, by controlling the potential to be applied to the light-shielding film, the smear is reduced. In other words, when the light-shielding film is uniformly connected to the GND potential, it is impossible to control the voltage to be applied to the light-shielding film due to the control of other operations, for example, the operation for reducing the smear.

### SUMMARY OF THE INVENTION

An object of an illustrative, non-limiting embodiment of the invention is to provide a CCD type solid-state imaging device which not only can apply a reference potential to a channel stop stably to hold the potential of a semiconductor substrate at the reference potential but also can control a voltage to be applied to a light-shielding film for improving the performance of the device such as the reduction of smear and the lowering of a read-out voltage, and a method for manufacturing such CCD type solid-state imaging device.

According to an aspect of the invention, there is provided a CCD type solid-state imaging device including: a semiconductor substrate having a light receiving area on a surface thereof; a plurality of photodiodes comprising photodiodes arrays arranged in the light receiving area; a plurality of first charge transfer paths arranged side by side with the respective photodiodes arrays; a second charge transfer path connected to end portions of the first charge transfer paths, the second charge transfer path transferring charges from the first charge transfer paths to an output end of the second charge transfer path; a channel stop of a first high density impurity region, the channel stop having a linear shape and separating mutually adjoining sets from each other, each set comprising a photodiode array and a first charge transfer path arranged side by side with the first charge transfer path; a first light-shielding film made of metal, the first light-shielding film being stacked above the light receiving area and having openings above the respective photodiodes, a control pulse voltage being applied to the first light-shielding film; a second light-shielding film made of metal, the second light-shielding film being spaced from the first light-shielding film and covering a connecting portion between the second charge transfer path and the light receiving area; and a contact portion of a second high density impurity region, the contact portion connecting the channel stop and the second light-shielding film and applying a reference potential to the channel stop.

The CCD type solid-state imaging device may further include a third light-shielding film made of metal, the third-light shielding film covering a clearance between the first and second light-shielding films and being connected to the second light-shielding film.

The CCD type solid-state imaging device may further include: a third high density impurity region existing continuously with the channel stop and surrounding, for example in a ring shape, an outer periphery of the contact portion, wherein the contact portion is spaced from the third high density impurity region; and a connecting portion of a fourth high density impurity region having a linear shape and connecting the contact portion and the third high density impurity region.

In the CCD type solid-state imaging device, the connecting portion may be extended from the contact portion to the third high density impurity region in parallel to a direction where the first charge transfer paths extend.

In the CCD type solid-state imaging device, the connecting portion may be extended from the contact portion to the third high density impurity region in parallel to a direction where the second charge transfer path extends.

In the CCD type solid-state imaging device, the photodiodes arranged in even lines may be shifted by ½ pitch from the photodiodes arranged in odd lines, and the first charge transfer paths may be arranged to meander.

According to an aspect of the invention, there is provided a method for manufacturing the above CCD type solid-state imaging device, which includes forming a first light-shielding film and a second light-shielding film at the same time to provide a clearance between the first and second light-shielding films.

According to an aspect of the invention, there is provided a method for manufacturing the above CCD solid-state imaging device, which includes: forming a second high density impurity region including a contact portion on a surface of a semiconductor substrate according to an ionized metal plasma method; forming an insulating layer on the high density impurity region; opening up a contact hole in the insulating layer, the contact hole reaching the contact portion; and forming a second light-shielding film on the insulating layer to electrically connect the second light-shielding film and the contact portion.

### BRIEF DESCRIPTION OF THE DRAWINGS

The features of the invention will appear more fully upon consideration of the exemplary embodiments of the inventions, which are schematically set forth in the drawings, in which:

FIG. 1 is a view of the surface of a CCD type solid-state imaging device according to an exemplary embodiment of the invention;

FIG. 2 is an explanatory view of the position relationship between a light receiving area (image capturing area) and light-shielding films in the CCD type solid-state imaging device shown in FIG. 1;

FIG. 3 is an enlarged view of a rectangular frame III shown by a dotted line in FIG. 2;

FIG. 4 is a section view of a portion shown by the line IV-IV shown in FIG. 3;

FIGS. 5A to 5D are explanatory views of a procedure for manufacturing the structure portion shown in FIG. 4;

FIG. 6 is a section view of a portion shown by the line IV-IV shown in FIG. 3;

FIGS. 7A and 7B are voltage waveform views to explain the control of a voltage to be applied to a light-shielding film which is stacked on the light receiving area shown in FIG. 2;

FIG. 8 is a graphical representation of the smear-incident ray angle dependence, that is, the relationship between the smear amounts and incident ray angles, when a voltage to be applied to the light-shielding film stacked on the light receiving area shown in FIG. 2 is varied;

FIG. 9 is a graphical representation of the relationship between the applied voltages of the light-shielding film to be stacked on the light receiving area shown in FIG. 2 and depletion voltages;

FIG. 10 is a graphical representation of the relationship between the applied voltages of the light-shielding film to be stacked on the light receiving area shown in FIG. 2 and read-out gate-off voltages;

FIG. 11 is a graphical representation of the relationship between the applied voltages of the light-shielding film to be stacked on the light receiving area shown in FIG. 2 and breakdown voltages;

FIG. 12 is a view of the surface of a GND potential connecting portion according to a further exemplary embodiment of the invention; and

FIG. 13 is a view of the surface of a GND potential connecting portion according to a still further exemplary embodiment of the invention.

### DETAILED DESCRIPTION OF THE EXEMPLARY EMBODIMENTS

Although the invention will be described below with reference to the exemplary embodiment thereof, the following exemplary embodiment and its modification do not restrict the invention.

According to an exemplary embodiment of the invention, since the second light-shielding film for applying the reference potential to the channel stop is disposed spaced from the first light-shielding film for covering the light receiving area, while holding the semiconductor substrate in the reference potential stably, the application of the control pulse voltage to the first light-shielding film is controlled to thereby be able to reduce the smear and the like.

Now, description will be given below of an exemplary embodiment of the invention with reference to the accompanying drawings.

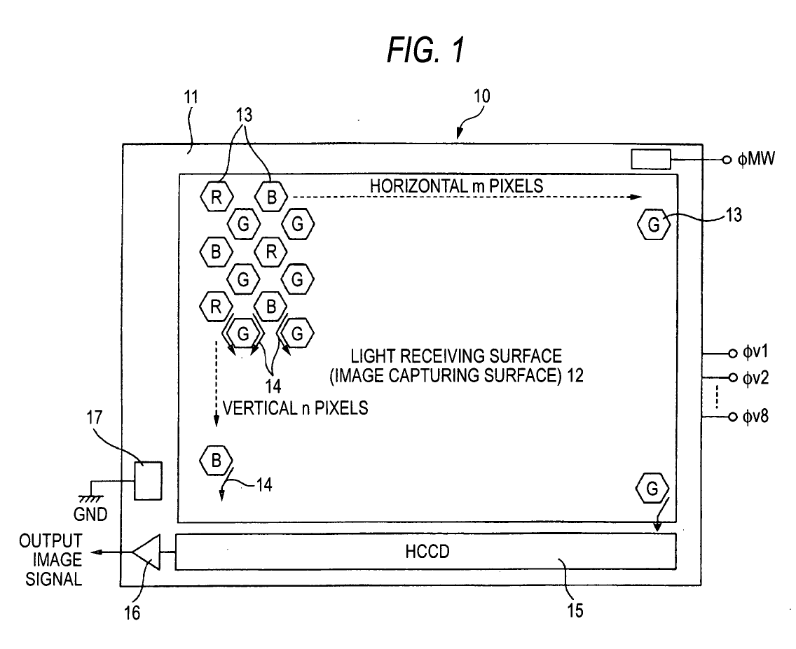

FIG. 1 is a view of the surface of a CCD type solid-state imaging device according to an exemplary embodiment of the invention. On the semiconductor substrate 11 of this CCD type solid-state imaging device 10, there is provided a light receiving area (image capturing area) 12 and, on the light receiving area 12, there are disposed a large number of photodiodes (photoelectric conversion elements: pixels) 13 in such a manner that they are arranged in a two-dimensional array. In the CCD type solid-state imaging device 10 shown in FIG. 1, the photodiodes 13 arranged in even lines are shifted by ½ pitch with respect to the photodiodes arranged in odd lines, respectively (this is referred to as a so called honey-comb pixel arrangement).

The terms “R”, “G”, and “B” shown on the respective photodiodes 13 in FIG. 1 respectively express the colors (red=R, green=G and blue=B) of color filters stacked above the photodiodes 13, while each of the photodiodes 13 stores therein a signal charge corresponding to the light receiving amount of one color of the three primary colors. By the way, in FIG. 1, there is shown an example in which primary-color system color filters are used; however, complementary-color system color filters may also be used.

In the horizontal direction of the semiconductor substrate 11, there are provided vertical transfer electrodes (not shown) which respectively meander in such a manner as to avoid the respective photodiodes 13. Also, in the semiconductor substrate 11, there are provided embedded channels (not shown) beside the photodiode arrays arranged in the vertical direction in such a manner that the channels meander in the vertical direction so as to avoid their associated photodiodes 13.

Each of the embedded channels and a vertical transfer electrode, which is provided on the embedded channel and arranged so as to meander in the vertical direction, cooperate together in constituting a vertical charge transfer path (VCCD) 14. When read-out pulses or vertical transfer pulses φV1˜φV8 (in the shown example, 8 phases are driven) are applied to the vertical charge transfer path 14 from externally, the stored charges of the photodiodes 13 are read out to the vertical charge transfer path 14 and are then transferred on the vertical charge transfer path 14.

On the lower side portion of the semiconductor substrate 11, there is provided a horizontal charge transfer path (HCCD) 15. This horizontal charge transfer path 15 is also composed of embedded channels and a horizontal transfer electrode disposed on the embedded channels. The horizontal charge transfer path 15 is two-phase driven by horizontal transfer pulses φH1 and φH2 which are supplied from externally.

On the output end portion of the horizontal charge transfer path 15, there is disposed an output amplifier 16. The output amplifier 16 outputs, as an image signal, a voltage value signal corresponding to the charge amount of a signal charge that has been transferred up to the end portion of the horizontal charge transfer path 15.

In the arbitrary positions of the semiconductor substrate 11 that avoid the light receiving area 12, horizontal charge transfer path 15 and the like, there are disposed connecting pads 17 and 18. To the connecting pad 17, there is connected the GND potential; and, to the connecting pad 18, there is applied a control pulse φMV from externally.

By the way, in the above description, there have been used the terms “vertical” and “horizontal”. Specifically, one of them means “one direction” which extends along the surface of the semiconductor substrate, while the other means “the other direction” which extends substantially at right angles to the “one direction”.

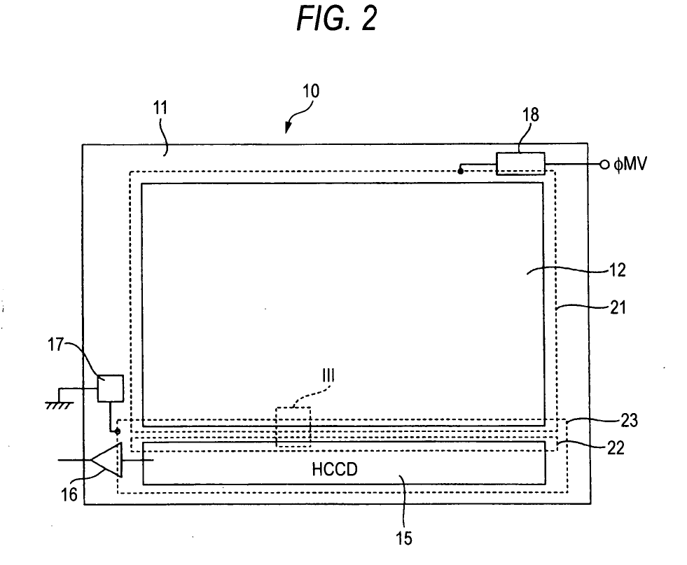

Now, FIG. 2 shows the existing area of a light-shielding film in the CCD type solid-state imaging device 10 shown in FIG. 1. In the CCD type solid-state imaging device 10 according to the present embodiment, there are disposed three light-shielding films 21, 22 and 23.

The light-shielding film 21 has a rectangular shape and is made of, for example, a tungsten metal film. This light-shielding film 21 covers the entire area of the light receiving area 12 and, of course, it has openings respectively opened up therein upwardly of their associated photodiodes. The edge of the light-shielding film 21, which exists on the horizontal charge transfer path 15 side, is disposed on a boundary portion between the horizontal charge transfer path 15 and light receiving area 12.

The light-shielding film 22 is made of, for example, a tungsten metal film. The light-shielding film 22 has a long rectangular shape extending along the horizontal charge transfer path 15 and covers a portion of the upper side (light receiving area 12 side) of the horizontal charge transfer path 15; and, the edge of the light-shielding film 22 on the light receiving area 12 side is spaced slightly from the light-shielding film 21 and is disposed on a boundary portion between the horizontal charge transfer path 15 and light receiving area 12.

The light-shielding film 23 has a rectangular shape and is made of, for example, an aluminum film. The light-shielding film 23 covers the entire area of the horizontal charge transfer path 15, while the edge of the light-shielding film 23 on the light receiving area 12 side is disposed at a position which is coincident with the edge of the light receiving area 12. In FIG. 2, the light-shielding film 23 is shown in such a manner that it covers a portion of the light receiving area 12; however, this illustration is used to avoid the superimposition of lines shown in FIG. 2. Actually, the light-shielding film 23 will never cover the photodiode 13.

The connecting pad 17 to be connected to the GND potential is electrically connected to the light-shielding film 23, while the light-shielding film 23, as will be described later, is electrically connected to the light-shielding film 22. The connecting pad 18, to which the control pulse φMV is to be applied, is electrically connected to the light-shielding film 21 and, as will be discussed later, the light-shielding film 21 is disposed in such a manner that it is spaced from the light-shielding film 23.

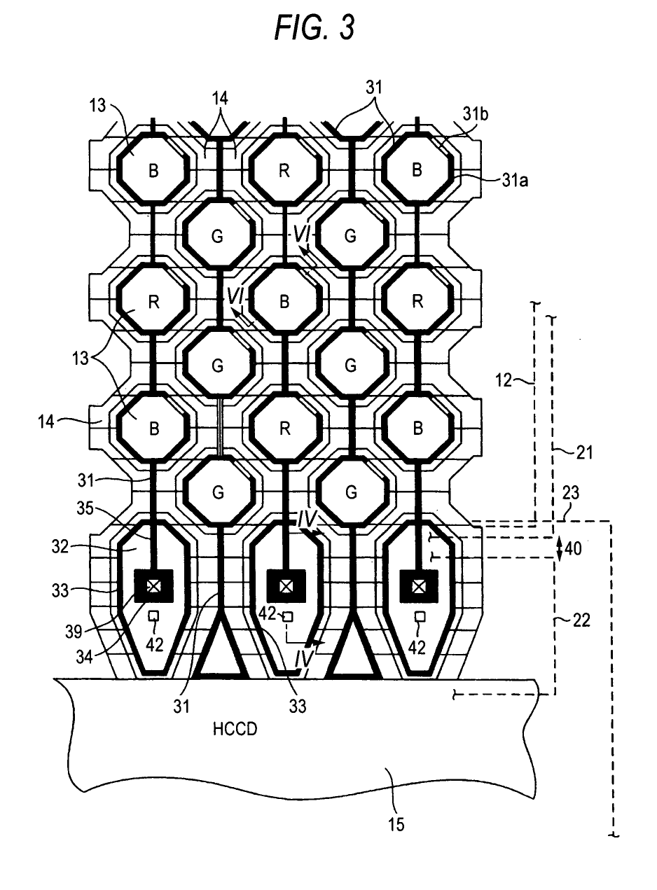

Now, FIG. 3 is an enlarged view of a rectangular shape frame III shown by a dotted line in FIG. 2, and is an enlarged view of a boundary portion between the horizontal charge transfer path 12 and light receiving area 12. Here, a photodiode 13 and a vertical charge transfer path 14 which, in the illustrated example, exists on the right in FIG. 3, cooperate together in forming a set. Such sets are respectively separated from their adjoining sets by their associated channel stops 31 that extend in the vertical direction. And, the photodiodes 13 are separated from their adjoining photodiodes 13 by their associated channel stops 31 and pixel separation regions 31a which are respectively arranged continuously with their associated channel stops 31.

The channel stop 31 and pixel separation region 31a are respectively formed of a p+ region. In the illustrated example, in the right oblique upper position of each of the photodiodes 13, there is arranged a signal read-out portion 31b in which the p+ region is not formed. From this signal read-out portion 31b, there is read out the signal charge of the photodiode 13 to its adjoining vertical charge transfer path 14. By the way, the end portion of each cannel stop 31 on the opposite side to the horizontal charge transfer path 15, similarly to the prior art, is connected to the GND potential.

The vertical charge transfer path 14 is composed of an embedded channel (n region) provided in the p well layer of the surface portion of an n-type semiconductor substrate 11 and a transfer electrode which is made of a poly-silicone film and is disposed on the embedded channel; and, the transfer electrode, as shown in FIG. 3, is formed to have such a size that allows provision of two transfer electrodes with respect to one photodiode.

In the CCD type solid-state imaging device 10 according to the present embodiment, a photodiode forming area 32 nearest to the horizontal charge transfer path (HCCD) 15 is used as a GND potential connecting portion 32. The entire periphery of each GND potential connecting portion 32 is surrounded by a p+ region 33 which has the same width as the channel stop 31 and pixel separating area 31a; and, in the interior of the GND potential connecting portion 32, there is provided an island-like-shaped p+ region (contact portion) 34 which is spaced from the p+ region 33 that exists on the periphery of the GND potential connecting portion 32. And, the island-like-shaped contact portion 34 is connected to the p+ region 33 existing on the outer periphery of the portion 32 by a p+ region (connecting portion) 35 which extends in the vertical direction. The width of the p+ region 35, in the example shown in FIG. 3, is set to be identical with that of the channel stop 31.

Here, the term “island-like-shaped” is used to express that the contact portion 34 is spaced from the channel stop 33 which is formed in a ring shape on the outer periphery of the GND potential connecting portion 32.

The GND potential connecting portion 32 is formed long in the vertical direction when compared with the photodiode 13 which stores the signal charge therein. The reason for use of this shape is that the connecting portions between the vertical charge transfer paths 14 and horizontal charge transfer path 15 can provide snap pitches.

By the way, in the illustrated example, the vertical charge transfer paths 14 are directly connected to the horizontal charge transfer path 15. However, in some cases, between the vertical charge transfer paths 14 and horizontal charge transfer path 15, there may also be interposed a signal charge buffer area (memory portion) which stores a signal charge temporarily for a pixel mix or the like.

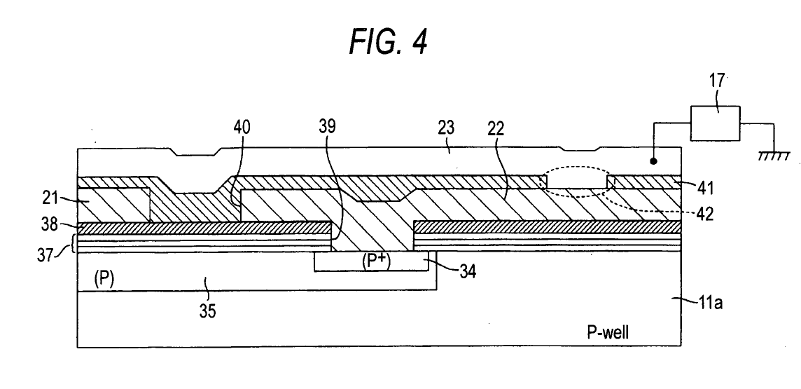

Now, FIG. 4 is a section view taken along the IV-IV line position shown in FIG. 3 and also is a section view of the GND potential connecting portion 32 in the vertical direction. As regards the GND potential connecting portion 32 which is provided in the p well layer 11a formed in the surface portion of an n-type semiconductor substrate, the outer periphery of the GND potential connecting portion 32 is separated in a ring shape (which is not shown in FIG. 4: see FIG. 3) from the remaining areas of the GND potential connection portion 32; and, on the horizontal-direction outside of the GND potential connecting portion 32, there is disposed the n-type embedded channel of the vertical charge transfer path 14 (which is not shown in FIG. 4). Also, in the central portion of the GND potential connecting portion 32, there is formed an island-like-shaped contact portion 34 which is spaced from the channel stop 33 and is composed of a P+ region. To this contact portion 34, there is connected a connecting portion 35 which is composed of a p+ region.

On the surface of the thus structured semiconductor substrate, there is stacked an insulating layer 37 having an ONO (oxide film-nitride film-oxide film) structure and, on the insulating layer 37, there is stacked an insulating layer 38 which is composed of a silicone oxide film.

In the portion of the insulating layers 37 and 38 that exists upwardly of the contact portion 34, there is opened up a contact hole 39 and, on the upper surface of the insulating layer 38, there is stacked the light-shielding film 22 which is made of tungsten W, whereby the light-shielding film 22 is connected to the contact portion 34 electrically. Simultaneously when the light-shielding film 22 is stacked, the light-shielding film 21 is stacked. At the then time, between the light-shielding films 22 and 21, there is interposed a space portion 40.

On the upper surfaces of the light-shielding films 21 and 22, there is stacked a silicone oxide film 41. In the proper portion of the silicone oxide film 41 existing upwardly of the light-shielding film 22, there is opened up a contact hole 42 which reaches the light-shielding film 22. And, on the upper surface of the silicone oxide film 41, there is stacked an aluminum film, thereby providing a light-shielding film 23. The light-shielding film 23 is electrically connected to the light-shielding film 22 through the contact hole 42.

The light-shielding film 23 is electrically connected to the connecting pad 17, whereby the contact portion 34, that is, the semiconductor substrate 11 is connected to the GND potential through the contact hole 39/light-shielding film 22/contact hole 42/light-shielding film 23.

The light-shielding film 21 is electrically connected to the connecting pad 18, whereby, as will be described later in detail, a voltage to be applied to the light-shielding film 21 can be controlled.

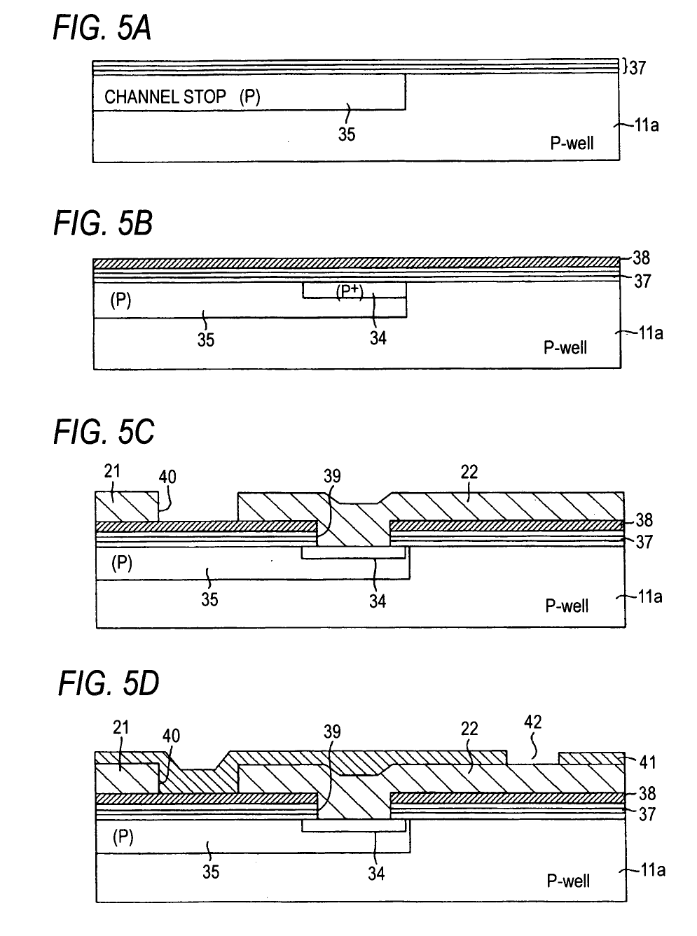

Now, FIGS. 5A to 5D are explanatory views of a procedure for manufacturing the GND potential connecting portion shown in FIG. 4. Firstly, as shown in FIG. 5A, the connecting portion 35 is formed in the p well layer 11a simultaneously with the channel stop 31 according to an ion metal plasma (IMP) process. By the way, although the connecting portion 35 is shown as “p region”, this shows only that the connecting portion 35 is slightly lower in the impurity density than the contact portion 34; that is, actually, the connecting portion 35 is higher in the impurity density than the p well layer 11a. Also, on the surface of the semiconductor substrate 11, there is stacked the insulating layer 37 having the ONO structure.

Next, as shown in FIG. 5B, the contact portion 34 is formed according to the IMP process and, on the insulating layer 37, there is stacked the insulating layer 38 which is made of a silicone oxide film.

Next, as shown in FIG. 5C, in the insulating layers 37 and 38, there is opened up the contact hole 39 by etching and, after then, on the insulating layers 37 and 38, there are stacked the tungsten films 22 and 21. As a result of this, the light-shielding film 22 and contact portion 34 are electrically connected to each other.

Next, as shown in FIG. 5D, on the upper surface of the light-shielding film 22, there is stacked the silicone oxide film 41 and, in the proper portion of the silicone oxide film 41, there is opened up the contact hole 42. After then, when there is stacked an aluminum film on the upper surface of the silicone oxide film 41, there can be provided the state that is shown in FIG. 4.

In the thus structured CCD type solid-state imaging device 10, as shown in FIG. 3, in the portion of the vertical charge transfer path 14 that exists in the neighborhood of the horizontal charge transfer path 15, the vertical charge transfer path 14 remains held by and between the channel stops 31 and 33 both of which are narrow in width; and, therefore, the physical condition of the transfer of the signal charge in the early transfer stage is the same as in the later transfer stage.

Also, since the light-shielding films 21 and 22 are spaced apart from each other, individual potentials can be applied to them and, because the space portion 40 interposed between the light-shielding films 21 and 22 is shielded from the light by the light-shielding film 23 disposed on the upper portion of the space portion 40, there is no possibility that the shielding of the light can be incomplete.

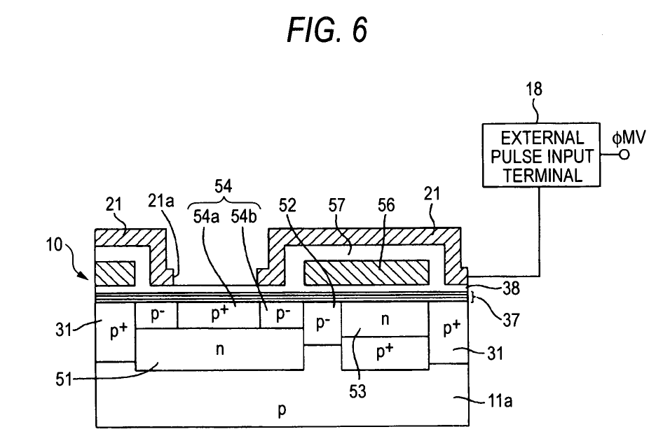

Now, FIG. 6 is a section view taken along the line VI-VI shown in FIG. 3 and, specifically, it is a section view of a solid-state imaging device which is array-formed on the light receiving area and corresponds substantially to one pixel. Pixels on the light receiving area are respectively formed on the p well layer l1a formed in the surface portion of the n-type semiconductor substrate. On the surface portion of the p well layer 11a, there is provided an n-type area portion 51, thereby providing the photodiode 13 (“51” is also hereinafter referred to as a photodiode) which is shown in FIG. 1 and carries out photoelectric conversion between the p well layer 11a and itself.

On the adjoining pixel side of the n-type area portion (photodiode) 51, there is provided a channel stop (an element separation region: a p+ region); and, on the opposite side of the photodiode 51, there is provided an n region 53 through a read-out gate portion (a p− region). This n region 53 constitutes the embedded channel of the vertical charge transfer path 14.

On the surface portion of the n-type area portion 51, there is provided a high density impurity surface layer 54 of a reverse conduction type (p type). Owing to the provision of the high density impurity surface layer 54, free electrons generated as a dark current are caught by the holes of the high density impurity surface layer 54 to thereby prevent the dark current from appearing in an image as a white stain.

The high density impurity surface layer 54 according to the present embodiment is provided in such a manner that it is divided to a central high density portion (p+ region) 54a existing on the surface of the n-type area portion 51 and a low density portion (p− region) 54b disposed on the peripheral portion thereof. The reason why the peripheral portion of the high density impurity surface layer 54 is formed as the low density portion 54b is that the electric field of the peripheral portion can be weakened and also that a voltage, which is used when reading out the stored charge of the photodiode (n-type area portion) 51 to the embedded channel 53 of the vertical transfer path, can be lowered.

The upper-most surface of the p well layer 11a, in which the photodiode 51, embedded channel 53 and the like are provided, is covered with an insulating layer 37 having the ONO (oxide film-nitride film-oxide film) structure, and the top surface of the upper-most surface of the p well layer 11a is further covered with an insulating layer 38 formed of a single layer which is made of silicone oxide or the like. On the portion of the insulating layer 38 that exists just above the embedded channel 53, there is stacked a vertical transfer electrode film (for example, a poly-silicone film) 56.

Upwardly of the vertical transfer electrode film 56, through an insulating layer 57, there is stacked the light-shielding film 21 which is made of a tungsten metal film and has already been explained with reference to the FIGS. 2 and 3. In the portions of the light-shielding film 21 that exist just above the respective photodiodes 51, there are formed openings 21a. Incident rays are allowed to enter the n-type area portion 51 through these openings 21a.

Also, in the solid-state imaging device 10 according to the present embodiment, the end portion of the light-shielding film opening 21a is extended up to the position that covers the low density portion 54b of the high density impurity surface layer 54. To this light-shielding film 21, there is connected the pad (the input terminal of the external pulse φMV) 18 shown in FIG. 2.

On the light-shielding film 21, there is stacked a transparent flattened layer (not shown), on the surface of the flattened layer the surface of which is formed flat, there is stacked a color filter layer (not shown) and, on the color filter layer, there is stacked a micro lens.

When an image is picked up using the thus structured solid-state imaging device 10, incident rays coming from an image pickup field are radiated onto the light receiving area 12 (FIG. 1) of the solid-state imaging device 10. When the incident rays are radiated onto the respective photodiodes 13 (in FIG. 6, “51”), in the respective photodiodes 51, there are stored signal charges (in this example, electrons) which correspond to the amounts of their associated incident rays.

When an image pickup control part (not shown) outputs a read-out pulse to the solid-state imaging device 10, this read-out pulse is applied to the vertical transfer electrode 56 which functions also as a read-out electrode. As a result of this, the stored charges (signal charges) within the photodiodes 51 are read out through the read-out gate portion 52 to the embedded channels 53 respectively.

When the image pickup control part (not shown) outputs a vertical transfer pulse φV and a horizontal transfer pulse φH to the solid-state imaging device 10, the respective signal charges on the vertical charge transfer paths 14 shown in FIG. 1 are transferred every transfer electrode. And, when the signal charges corresponding to one line of photodiodes are transferred to the horizontal charge transfer path 15, such signal charges corresponding to one line of photodiodes are transferred on the horizontal charge transfer path 15, with the result that the amplifier 16 reads out voltage value signals respectively corresponding to the charge amounts of the respective signal charges.

In such signal charge read-out operation, the solid-state imaging device 10 according to the present embodiment controls a pulse voltage φMV which is applied to the light-shielding film 21 by the image pickup control part. Next, description will be given below of the control of the voltage to be applied to the light-shielding film 21.

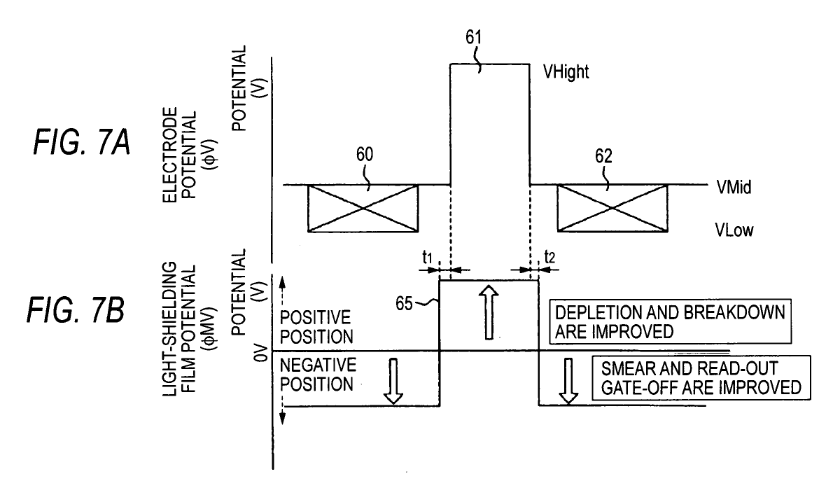

FIG. 7A is shows a pulse waveform to be applied to the vertical transfer electrode (which functions also as a read-out electrode), and FIG. 7B shows a pulse waveform to be applied to the light-shielding film 21.

Before the signal charges are read out to the vertical charge transfer path 14 from the photodiode 51, the vertical charge transfer path 14 is driven using a high speed sweep pulse (for example, Vmid=0V, Vlow=−8V) 60. As a result of this, unnecessary charges on the vertical charge transfer path 14 are swept out from the vertical charge transfer path 14.

Next, when a read-out pulse (for example, Vhigh=15V) is applied to the vertical transfer electrode functioning also as a read-out electrode, the stored charges of the photodiodes 51 are respectively read out to the embedded channel 53 of the vertical charge transfer path 14. And, by driving the vertical charge transfer path 14 using a transfer pulse 62, the signal charges are transferred in the direction of the horizontal charge transfer path 15.

At the then time, a pulse voltage (φMV) 65 is applied to the light-shielding film 21 through the pad 18. This pulse voltage 65 is a pulse voltage which synchronizes with the read-out pulse 61. The high level potential of the pulse voltage 65 is controlled to be a potential having the same polarity as the read-out pulse 61, in this example, a given positive potential; and the low level potential thereof is controlled to be a potential having the opposite polarity to the read-out pulse 61, in this example, a given negative potential.

The light-shielding film 21 is always controlled to be a given negative potential, except when reading out a signal charge from the photodiode 51 to the embedded channel 53. And, when the read-out pulse 61 is applied to the vertical transfer electrode serving also as a read-out electrode, according to the present embodiment, a given positive potential is applied to the light-shielding film 21 earlier by a given time t1 than the read-out pulse 61. When the read-out pulse 61 is ended, the light-shielding film 21 is returned back to a given negative potential later by a given time t2 than the end time of the read-out pulse 61. Here, there may be t1=t2 or t1≠t2.

By the way, in FIG. 7B, the pulse waveform of the voltage 65 to be applied to the light-shielding film 21 is shown in the form of a square wave. However, this may also be a trapezoidal wave.

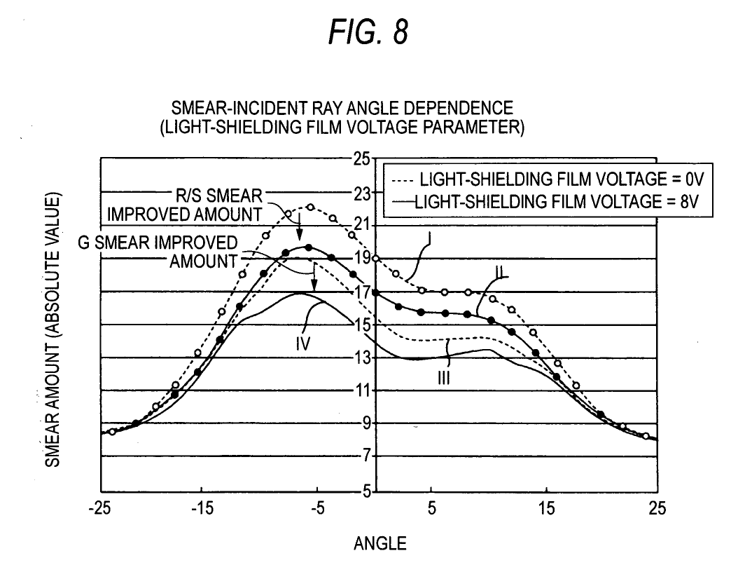

Now, FIG. 8 is a graphical representation of measured data showing an improvement in the smear characteristic of the solid-state imaging device 10 according to the present embodiment. When the applied voltage of the light-shielding film 21 is always fixed to “0V”, the smear absolute amounts with respect to the incident angles of the incident rays provide such amounts as shown by characteristic lines I and II in FIG. 8. Specifically, the characteristic line I shows the smear characteristic which is contained in the signal charge of a red color (R) or a blue color (B), while the characteristic line II expresses the smear characteristic that is contained in the signal charge of a green color (G).

On the other hand, as in the solid-state imaging device 10 according to the present embodiment, when the applied voltage of the light-shielding film 21 is controlled to a given negative potential (for example, −8V), like a characteristic line III (the smear characteristic of R or B) and a characteristic line IV (the smear characteristic of G) respectively shown in FIG. 8, it is found that the smear characteristic is improved about 20% when compared with the characteristic lines I and II.

The reason for such improvement may be that, by applying the negative potential to the light-shielding film 21, the invasion of electrons into the embedded channel 53 through the insulating layers 37 and 38 interposed between the p well layer 11a and the end portion of the opening 21a of the light-shielding film 21 can be prevented. Accordingly, it can be expected that, by further increasing the negative potential to be applied to the light-shielding film 21, the smear improvement ratio can be enhanced.

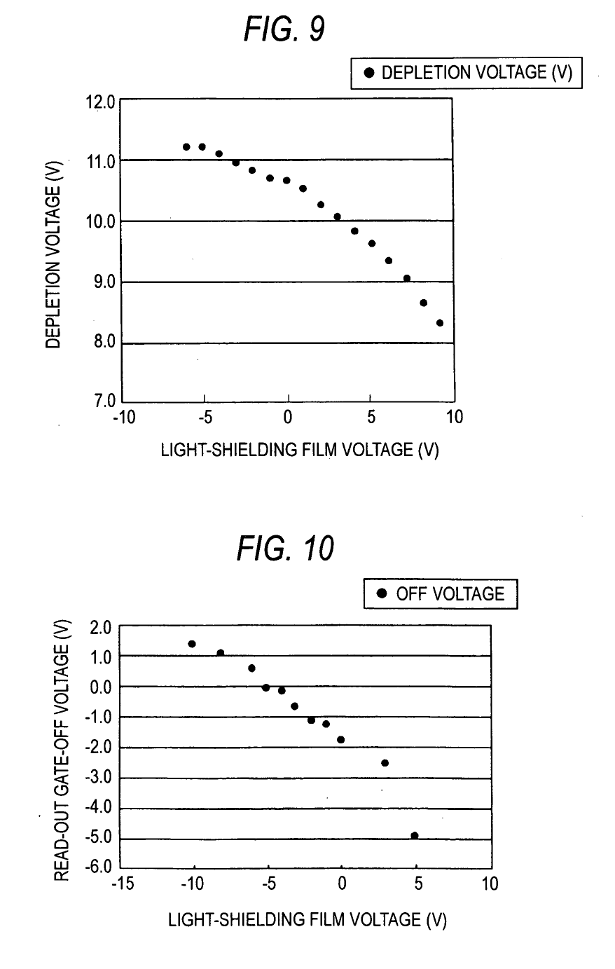

Now, FIG. 9 is a graphical representation of measured data on variations in a depletion voltage with respect to the applied voltage of the light-shielding film 21. It can be found from the distribution of data on actually measured points that the higher the applied voltage of the light-shielding film 21 is, the more the depletion can be improved. The data in FIG. 9 show that, when the depletion voltage is required to be equal or less than 10V, the applied voltage of the light-shielding film 21 may be set equal to or higher than +3V.

When the signal charges are read out from the photodiodes to the vertical charge transfer paths, according to the present embodiment, a given positive potential is applied to the light-shielding film 21. When the given positive potential is set for a potential equal to or higher than “+3V” based on the data shown in FIG. 9, the depletion voltage can be controlled to a voltage equal to or lower than 10V, thereby being able to facilitate the movements of the signal charges (electrons) from the photodiodes to the vertical charge transfer paths. That is, the above setting of the given positive potential can assist the movements of the electrons.

At the then time, according to the present embodiment, as shown in FIG. 6, since the light-shielding film 21 is disposed at a position to cover the low density portion 54b of the high density impurity surface layer 54, the light-shielding film 21 functions as a gate electrode, thereby being able to move the signal charges of the n-type area portion 51 to the embedded channel 53 more easily.

Now, FIG. 10 is a graphical representation of measured data on variations in a read-out gate-off voltage with respect to the applied voltage of the light-shielding film 21. In the solid-state imaging device 10 according to the present embodiment, the voltage to be applied to the light-shielding film 21 is controlled to a given negative voltage at all timings except for timings for reading out the signal charges to the vertical charge transfer paths. Owing to this, the potential of the read-out gate 52 is lowered except the time for reading out the signal charges, which makes it possible to increase the off voltage.

FIG. 10 shows that, when the off voltage is required to be equal to or higher than 0V, the voltage to be applied to the light-shielding film 21 may be −5V or lower. That is, by applying the negative voltage to the light-shielding film 21 at the time except the signal charge read-out time, it is possible to prevent the signal charges (electrons) from moving from the photodiodes 51 to the embedded channel 53 at timings independent of the reading of the signal charges. Also, it can be expected that, when the applied voltage of the light-shielding film 21 is lowered further, the off voltage characteristic can be improved further.

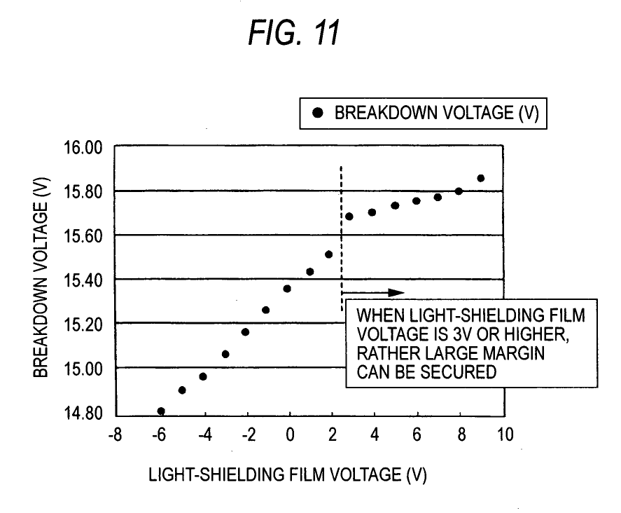

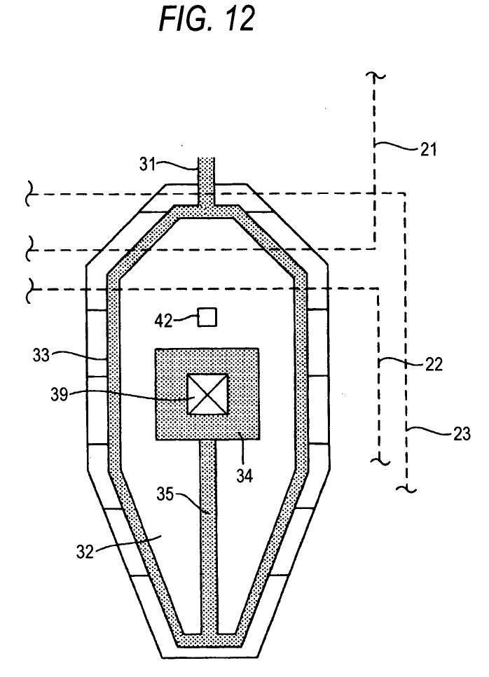

Now, FIG. 11 is a graphical representation of measured value data on variations in a break-down voltage with respect to the applied voltage of the light-shielding film 21. As described above, when the negative voltage is always applied to the light-shielding film 21, the smear can be reduced. However, in the signal charge read-out time, when the potential of the light-shielding film 21 is left in the negative potential, a potential difference between the light-shielding film 21 and read-out electrode (to which there is applied a voltage, for example, +15V) increases, which raises a fear that a breakdown phenomenon can occur in the element separation region 31 interposed between the light-shielding film 21 and its adjoining pixel.

According to the data shown in FIG. 11, the lower the applied voltage of the light-shielding film 21 is, the lower the breakdown voltage incurring the above breakdown phenomenon is, which makes it easy for the breakdown phenomenon to occur.

In view of the above, in the solid-state imaging device 10 according to the present embodiment, when reading out the signal charge from the photodiode 51 to the embedded channel 53 of the vertical charge transfer path 14, the applied voltage of the light-shielding film 21 is controlled to a given positive voltage earlier by a given time t1 than the turn-on of the read-out pulse 61 and later by a given time t2 than the turn-off of the read-out pulse 61.

Thanks to this, when reading out the signal charge, a potential difference between the light-shielding film and its adjoining pixel electrode can be reduced, thereby being able to avoid the occurrence of the breakdown. According to the data shown in FIG. 11, the characteristic curve of a voltage to be generated by the breakdown varies greatly with the light-shielding film applied voltage “+3V” as a boundary. Therefore, when the applied voltage of the light-shielding film 21 is controlled to be at least “+3V” or higher, the occurrence of the breakdown can be restricted effectively. Also, by further raising the positive voltage to be applied to the light-shielding film 21, a margin with respect to the breakdown can also be enhanced further.

As has been described heretofore, according to the present embodiment, not only because the pulse voltage to be applied to the light-shielding film 21 is applied while it is timed to the read-out pulse but also because the high and low level potentials of this pulse voltage are adjusted in the above-mentioned manner, there can be provided the following effects: that is, the smear characteristic of the image pickup device can be improved, the breakdown voltage can be improved, the depletion voltage can be improved, and the read-out gate-off voltage can be improved.

That is, according to the present embodiment, the above effects can be realized by employing the structure in which the light-shielding film 21 is disposed separately from the light-shielding films 22 and 23, the light-shielding films 22 and 23 are respectively connected to the GND potential, and a voltage to be applied to the light-shielding film 21 is controlled independently.

Also, according to the present embodiment, since there is not employed such structure that through-holes are opened up in the insulating layers 37 and 38 and elements (such as the high density impurity surface layer 54) formed on the semiconductor substrate are contacted directly with the light-shielding film 21 using a metal plug, there can be obtained the following effect as well: that is, there is no possibility that the surface of the semiconductor substrate can be contaminated with metal elements, thereby being able to eliminate a fear that the operation of a highly refined image pickup device can be hindered.

As has been described hereinabove, according to the solid-state imaging device of the present embodiment, as shown in FIG. 3, in the portion that is nearest to the horizontal charge transfer path 15, there is disposed the GND potential connecting portion 32 which corresponds to one line and the outer periphery of which is surrounded by the narrow channel stop 33; to the contact portion 34 that is disposed in an island-like manner within the GND potential connecting portion 32, there is connected through the contact (through hole) 39 the light-shielding film 22 which is separated from the light-shielding film 21; to the light-shielding film 22, there is connected the aluminum light-shielding film 23 through the contact (through hole) 42; the light-shielding film 23 is connected to the pad 17 which is connected to the GND potential; and, the light-shielding film 21 is connected to the pad 18 which provides an applied voltage control terminal. Thanks to this structure, not only, while holding the vertical charge transfer path on the same physical transfer condition in both of the early and late transfer stages, a stable GND potential can be applied to the channel stop, but also it is possible to take control of the voltage to be applied to the light-shielding film 21 for the purpose of improving the performance of the device such as the reduction of smear and the lowering of the read-out voltage.

In the embodiment shown in FIG. 3, there is provided the GND potential connecting portion 32 that corresponds to one line; however, it is also possible to provide the GND potential connecting portion 32 that corresponds to two or more lines. For example, when an region, which is nearest to the GND potential connecting portion 32 shown in FIG. 3 and in which there is provided a photodiode 13 with a color filter G, is also used as a GND potential connecting portion, a GND connecting portion corresponding to a total of two lines can be provided.

In this case, a p+ region for a contact to be provided in this area is separated from its peripheral channel stop 31 to thereby provide an island-like-shaped area, and the island-like-shaped p+ region is connected to the channel stop 31 by a narrow p+ region which extends in the vertical direction. Thanks to this, the GND potential can be applied to the respective arrays of channel stops 31 through the light-shielding films 22 and 23. Of course, since the light receiving area 12 retreats from the horizontal charge transfer path 15 by an amount corresponding to one line, the edge of the area for provision of the light-shielding film 21 on the horizontal charge transfer path 15 is also retreated toward the opposite side of the horizontal charge transfer path 15 by an amount corresponding to one line.

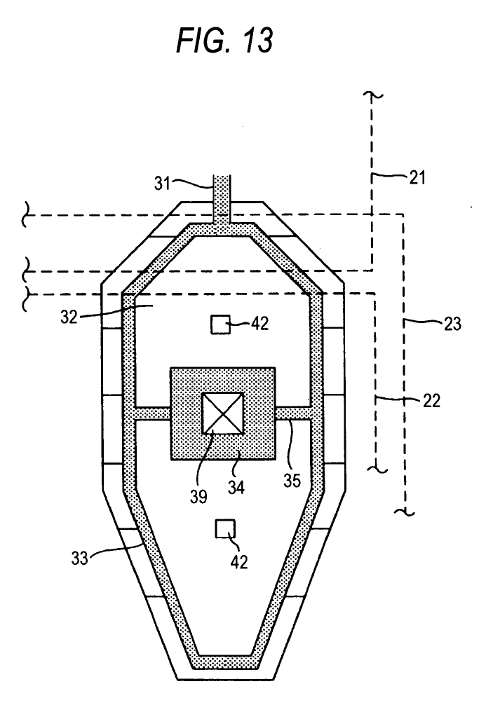

By the way, as a position where there is provided the contact 42 for connecting together the light-shielding films 22 and 23, there can be used any arbitrary position, provided that the light-shielding films 22 and 23 are superimposed on top of each other in such position. Also, as a position for provision of the connecting portion 35 for connecting the contact portion 34 disposed in an island manner within the GND potential connecting portion to the channel stop 33 existing on the outer periphery of the GND potential connecting portion, there can be selected any arbitrary position. For example, they may also be selected as shown in FIGS. 12 and 13.

Specifically, in the embodiment shown in FIG. 3, the connecting portion 35 is extended in the vertical direction from the light receiving area side and is connected to the contact portion 34. On the other hand, in an embodiment shown in FIG. 12, the connecting portion 35 is extended in the vertical direction from the horizontal charge transfer path 15 side. Also, in an embodiment shown in FIG. 13, the connecting portion 35 is extended in the horizontal direction. Here, in the embodiment shown in FIG. 13, there are provided two contacts 42 for connecting together the two light-shielding films 22 and 23. However, the number of contacts 42 may be one or a large number. This applies similarly in the embodiments respectively shown in FIGS. 12 and 3 as well.

A CCD type solid-state imaging device according to the invention can apply the GND voltage to the semiconductor substrate stably and also can read out and transfer the signal charge to the vertical charge transfer path properly. Therefore, the present CCD type solid-state imaging device is useful as a solid-state imaging device which is incorporated into a digital camera and the like.

While the invention has been described with reference to the exemplary embodiments, the technical scope of the invention is not restricted to the description of the exemplary embodiments. It is apparent to the skilled in the art that various changes or improvements can be made. It is apparent from the description of claims that the changed or improved configurations can also be included in the technical scope of the invention.

This application claims foreign priority from Japanese Patent Application No. 2006-125054, filed Apr. 28, 2006, the entire disclosure of which is herein incorporated by reference.

What is claimed is:

1. A method for manufacturing a CCD solid-state imaging device, comprising:
a semiconductor substrate having a light receiving area on a surface thereof;
a plurality of photodiodes comprising photodiodes arrays arranged in the light receiving area;
a plurality of first charge transfer paths arranged side by side with the respective photodiodes arrays;
a second charge transfer path connected to end portions of the first charge transfer paths, the second charge transfer path transferring charges from the first charge transfer paths to an output end of the second charge transfer path;
a channel stop of a first high density impurity region, the channel stop having a linear shape and separating mutually adjoining sets from each other, each set comprising a photodiode array and a first charge transfer path arranged side by side with the first charge transfer path;
a first light-shielding film made of metal, the first light-shielding film being stacked above the light receiving area and having openings above the respective photodiodes, a control pulse voltage being applied to the first light-shielding film;
a second light-shielding film made of metal, the second light-shielding film being spaced from the first light-shielding film and covering a connecting portion between the second charge transfer path and the light receiving area;
a contact portion of a second high density impurity region, the contact portion connecting the channel stop and the second light-shielding film and applying a reference potential to the channel stop, said method comprising:
forming the first light-shielding film and the second light-shielding film at the same time to provide a clearance between the first and second light-shielding films.

2. A method for manufacturing a CCD solid-state imaging device, comprising:
a semiconductor substrate having a light receiving area on a surface thereof;
a plurality of photodiodes comprising photodiodes arrays arranged in the light receiving area;
a plurality of first charge transfer paths arranged side by side with the respective photodiodes arrays;
a second charge transfer path connected to end portions of the first charge transfer paths, the second charge transfer path transferring charges from the first charge transfer paths to an output end of the second charge transfer path;
a channel stop of a first high density impurity region, the channel stop having a linear shape and separating mutually adjoining sets from each other, each set comprising a photodiode array and a first charge transfer path arranged side by side with the first charge transfer path;
a first light-shielding film made of metal, the first light-shielding film being stacked above the light receiving area and having openings above the respective photodiodes, a control pulse voltage being applied to the first light-shielding film;
a second light-shielding film made of metal, the second light-shielding film being spaced from the first light-shielding film and covering a connecting portion between the second charge transfer path and the light receiving area;
a contact portion of a second high density impurity region, the contact portion connecting the channel stop and the second light-shielding film and applying a reference potential to the channel stop;
a third high density impurity region existing continuously with the channel stop and surrounding an outer periphery of the contact portion, wherein the contact portion is spaced from the third high density impurity region; and
a connecting portion of a fourth high density impurity region having a linear shape and connecting the contact portion and the third high density impurity region, said method comprising:
forming the second high density impurity region including the contact portion on a surface of the semiconductor substrate according to an ionized metal plasma method;
forming an insulating layer on the high density impurity region;
opening up a contact hole in the insulating layer, the contact hole reaching the contact portion; and
forming the second light-shielding film on the insulating layer to electrically connect the second light-shielding film and the contact portion.
